(19) United States
(12) Patent Application Publication
(10) Pub. No.: US 2026/0247701 A1
(43) Pub. Date: Aug. 20, 2026

(54) SEMICONDUCTOR DEVICE INCLUDING TRANSISTORS WITH DIFFERENT THRESHOLD VOLTAGES

(71) Applicants: Ark HDPS Semiconductor Pte. LIMITED., Singapore (SG); Power systems thinker LTD., Hsinchu County (TW)

(72) Inventor: Chin-Fu Chen, Hsinchu County (TW)

(73) Assignees: Ark HDPS Semiconductor Pte. LIMITED., Singapore (SG); Power systems thinker LTD., Hsinchu County (TW)

(21) Appl. No.: 19/390,690

(22) Filed: Nov. 17, 2025

(30) Foreign Application Priority Data
Feb. 20, 2025 (CN) 202510187181.1

(51) Int. Cl. H10D 84/83

(52) U.S. Cl. CPC H10D 84/839

(57) ABSTRACT

A semiconductor device includes a trench disposed in a substrate and extending laterally along a first direction. A gate electrode is disposed in the trench. A first body region is disposed in the substrate and located in a first area. A second body region is located in the first area, disposed directly below and in direct contact with the first body region. The second body region has a doping concentration higher than that of the first body region. A source region is disposed within the first body region. A source contact penetrates the source region and extends downwards into the first body region. A drain region is disposed on a back side of the substrate.

### BACKGROUND OF THE INVENTION

### FIELD OF THE INVENTION

The present disclosure relates generally to semiconductor technology, and more particularly to a semiconductor device including transistors with different threshold voltages through the structure of the semiconductor device.

### DESCRIPTION OF THE PRIOR ART

Power transistors are usually used in power electronics technologies. Power metal-oxide-semiconductor field-effect transistors (MOSFETs) are the most commonly used components in power conversion systems. MOSFETs include a lateral structure, such as a laterally-diffused metal-oxide-semiconductor (LDMOS) FET, and a vertical structure, such as a trench gate MOSFET, where a gate is disposed in a trench.

In recent years, with the development of various electronic products, the power and layout density of power MOSFETs have increased. The trench gate MOSFET has advantages of smaller unit size and reduced parasitic capacitance, thereby being widely used in many different fields, such as battery management, power supplies, and charging systems. However, conventional trench gate MOSFETs still cannot satisfy the requirements of power transistors in various electronic applications in all aspects.

### SUMMARY OF THE INVENTION

In view of this, the present disclosure provides a semiconductor device that includes transistors with different threshold voltages, achieved through the structure of the semiconductor device. The semiconductor device improves the safe operating area (SOA) and satisfies the performance requirements of various electronic circuit applications.

According to some embodiments of the present disclosure, a semiconductor device is provided and includes a substrate, a trench, a gate electrode, a first body region, a second body region, a source region, a source contact, and a drain region. The substrate has a first conductivity type. The trench extends along a first direction and is disposed in the substrate. The gate electrode is disposed in the trench. The first body region has a second conductivity type and is disposed in the substrate, located in a first area. The second body region has the second conductivity type and is located in the first area. The second body region is disposed directly below and in direct contact with the first body region. The doping concentration of the second body region is higher than that of the first body region. The source region has the first conductivity type and is disposed in the first body region. The source contact penetrates the source region and extends downwards into the first body region. The drain region has the first conductivity type and is disposed on the back side of the substrate.

According to some embodiments of the present disclosure, a semiconductor device is provided and includes a substrate, a trench, a gate electrode, a source region, and a body region. The substrate has a first conductivity type. The trench extends along a first direction and is disposed in the substrate. The gate electrode is disposed in the trench. The source region has the first conductivity type and is adjacent to the gate electrode. The body region extends along the first direction and includes a first segment and a second segment. The first segment includes a first body region and a second body region. The second segment includes the first body region. The doping concentration of the second body region is higher than that of the first body region. The first segment constitutes a part of a first transistor having a first threshold voltage. The second segment constitutes a part of a second transistor having a second threshold voltage. The first threshold voltage is higher than the second threshold voltage.

According to one embodiment of the present disclosure, a semiconductor device is provided and includes a substrate, a trench, a gate electrode, a source region, and a plurality of body regions. The substrate has a first conductivity type. The trench extends along a first direction and is disposed in the substrate. The gate electrode is disposed in the trench. The source region has the first conductivity type and is adjacent to the gate electrode. The plurality of body regions extend along the first direction and are spaced apart from each other by the substrate. Each body region has a surface abutting the substrate. The surface includes a bottom surface extending along the first direction and a side surface extending along a third direction. Each body region includes a first body region with a lower doping concentration and a second body region with a higher doping concentration. The second body region is disposed below the first body region. When a bias voltage is applied to the gate electrode, a first current channel and a second current channel are formed. The first current channel enters each body region from the bottom surface, passes through both the second body region and the first body region, and reaches the source region. The second current channel enters each body region from the side surface, passes through the first body region and not through the second body region, and reaches the source region.

These and other objectives of the present invention will no doubt become obvious to those of ordinary skill in the art after reading the following detailed description of the preferred embodiment that is illustrated in the various FIG.s and drawings.

### BRIEF DESCRIPTION OF THE DRAWINGS

Aspects of the present disclosure are best understood from the following detailed description when read with the accompanying FIG.s. It is noted that, in accordance with the standard practice in the industry, various features may not be drawn to scale. In fact, the dimensions of the various features may be arbitrarily increased or reduced for clarity of discussion.

FIG. 1 is a schematic top view of a semiconductor device according to an embodiment of the present disclosure, in which the frame lines indicate a first area and a second area.

FIG. 2 is a schematic cross-sectional view of a semiconductor device, taken along line A-A in FIG. 1, according to an embodiment of the present disclosure.

FIG. 3 shows schematic cross-sectional views (a) and (b) of semiconductor devices, taken along line B-B in FIG. 1, according to some embodiments of the present disclosure.

FIG. 4 is a schematic top view of a semiconductor device according to another embodiment of the present disclosure, in which the frame lines indicate a first area, a first segment of a body region, and a second segment of the body region.

FIG. 5 shows schematic cross-sectional views (a), (b), (c), and (d) of semiconductor devices according to some embodiments of the present disclosure. In this figure, (a) and (b) each represent a cross-section of a second transistor taken along line D-D in FIG. 4, and (c) and (d) each represent a cross-section of a first transistor taken along line C-C in FIG. 4.

FIG. 6 is a schematic top view of a semiconductor device according to another embodiment of the present disclosure, in which the frame lines indicate a first area, a second area, a first segment of a body region, and a second segment of the body region.

FIG. 7 shows schematic cross-sectional views (a), (b), (c), and (d) of semiconductor devices according to some embodiments of the present disclosure. In this figure, (a) and (b) each represent a cross-section of a second transistor taken along line F-F in FIG. 6, and (c) and (d) each represent a cross-section of a first transistor taken along line E-E in FIG. 6.

FIG. 8 is a schematic top view of a semiconductor device according to another embodiment of the present disclosure, in which the frame lines indicate a first area, a second area, a first segment of a body region, and a second segment of the body region.

FIG. 9 shows schematic cross-sectional views (a), (b), (c), and (d) of semiconductor devices according to some embodiments of the present disclosure. In this figure, (a) and (b) each represent a cross-section of a second transistor taken along line H-H in FIG. 8, and (c) and (d) each represent a cross-section of a first transistor taken along line G-G in FIG. 8.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as "below" and/or "beneath" other elements or features would then be oriented "above" and/or "over" the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as "first," "second," and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms "coupled to" and "electrically connected to" include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to a semiconductor device that includes transistors with different threshold voltages, achieved through the structure of the semiconductor device. According to embodiments of the present disclosure, the configurations of a source contact, a source region, and/or a body region enable a semiconductor device including a first transistor with a first threshold voltage and a second transistor with a second threshold voltage connected in parallel without external circuit control. In these embodiments, the body region includes a first body region with a lower doping concentration and a second body region with a higher doping concentration. Therefore, the safe operating area (SOA) of the semiconductor device is improved, satisfying the performance requirements of power components in various electronic circuit applications.

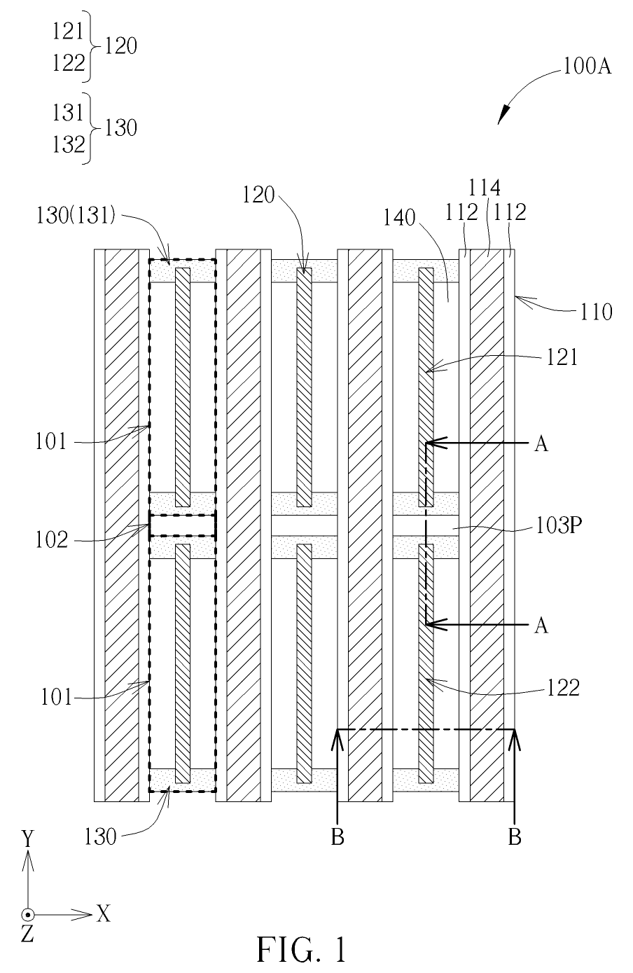

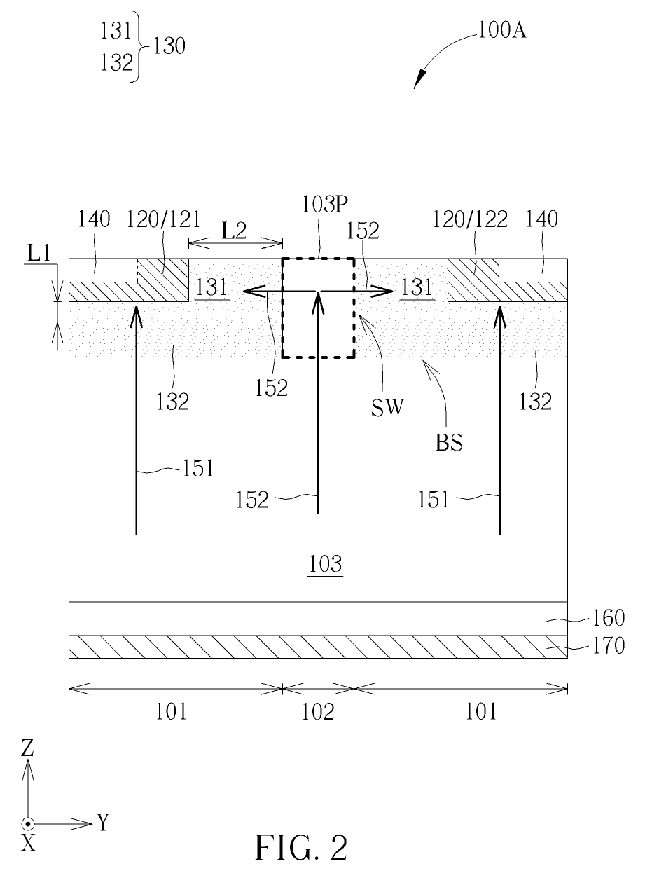

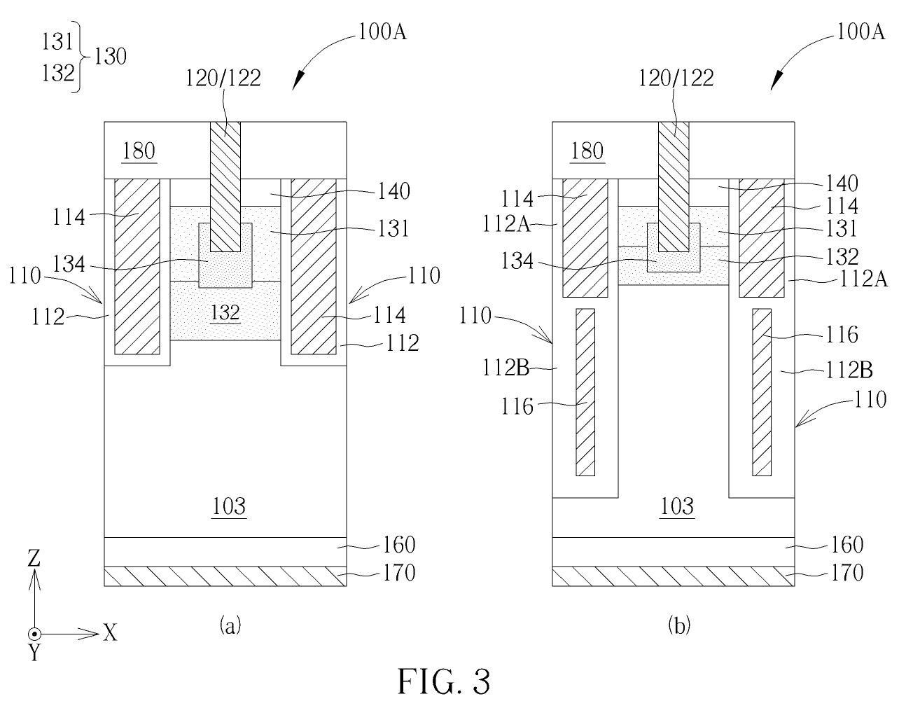

FIG. 1 is a top view of a semiconductor device 100A according to an embodiment of the present disclosure, in which the dashed frame lines indicate two first areas 101 and a second area 102. The second area 102 is located between the two first areas 101. FIG. 2 is a cross-sectional view of the semiconductor device 100A, taken along line A-A in FIG. 1, according to an embodiment of the present disclosure. FIG. 3 shows cross-sectional views (a) and (b) of the semiconductor device 100A according to some embodiments of the present disclosure, in which both the cross-sections (a) and (b) are taken along line B-B in FIG. 1. The cross-section (b) of FIG. 3 shows an embodiment of the semiconductor device 100A including a field plate 116, and the cross-section (a) of FIG. 3 shows another embodiment of the semiconductor device 100A without the field plate 116. Referring to FIGS. 1 and 3, the semiconductor device 100A includes a substrate 103, a trench 110, a gate electrode 114, a body region 130, a source region 140, a source contact 120, a drain region 160, and a drain electrode 170. In some embodiments, the substrate 103 has a first conductivity type, such as an n-type semiconductor substrate. The substrate 103 may also be referred to as an n-drift region. The trench 110 laterally extends along a first direction (e.g., the Y-axis direction) and is disposed in the substrate 103. In one embodiment, as shown in cross-section (a) of FIG. 3, the gate electrode 114 and a dielectric layer 112 are disposed in the trench 110. The dielectric layer 112 surrounds the side and bottom surfaces of the gate electrode 114, and the dielectric layer 112 may be used as a gate dielectric layer. In another embodiment, as shown in cross-section (b) of FIG. 3, the gate electrode 114, a dielectric layer 112A, the field plate 116, and a dielectric layer 112B are disposed in the trench 110. The field plate 116 is disposed below and vertically spaced apart from the gate electrode 114. The field plate 116 disperses the electric field, thereby improving the breakdown voltage of the semiconductor device. The dielectric layer 112A surrounds the side and bottom surfaces of the gate electrode 114, and the dielectric layer 112B surrounds the side and bottom surfaces of the field plate 116. The dielectric layer 112A may be used as a gate dielectric layer. In some embodiments, the composition of both the gate electrode 114 and the field plate 116 is, for example, polysilicon. The compositions of the dielectric layers 112, 112A and 112B are for example, silicon oxide, silicon nitride, or a combination thereof.

Referring to FIG. 1 and FIG. 3, the body region 130 has a second conductivity type, such as a p-type doped region. The body region 130 is disposed within the substrate 103 and located in the first area 101. The body region 130 includes a first body region 131 and a second body region 132. The second body region 132 is disposed directly below and in direct contact with the first body region 131. The doping concentration of the second body region 132 is higher than that of the first body region 131. Furthermore, the bottom surface of the second body region 132 is higher than the bottom surface of the gate electrode 114. The source region 140 has the first conductivity type, such as an n-type heavily doped region, and is disposed within the first body region 131. An interlayer dielectric (ILD) layer 180 is disposed above the substrate 103. The source contact 120 penetrates both the ILD layer 180 and the source region 140, and extends downwards into the first body region 131. In addition, the semiconductor device 100A includes a heavily doped region 134 having the second conductivity type, such as a p-type heavily doped region. The heavily doped region 134 is disposed directly below the source contact 120 and in direct contact with the bottom of the source contact 120. The heavily doped region 134 is embedded in the first body region 131 and in direct contact with the second body region 132. The doping concentration of the heavily doped region 134 is higher than that of the second body region 132. In some embodiments, the bottom surface of the heavily doped region 134 may be located in the first body region 131 or in the second body region 132. Alternatively, the bottom surface of the heavily doped region 134 may be on the same plane as the top surface of the second body region 132. The doping concentration of the heavily doped region 134 is higher than that of the first body region 131 and also higher than that of the second body region 132. This reduces the parasitic bipolar junction transistor (BJT) effect through the heavily doped region 134, which is beneficial for lowering the on-state resistance of the semiconductor device.

Referring to FIG. 1 and FIG. 2, the source contact 120 includes a first portion 121 and a second portion 122 spaced apart from each other in the first direction (e.g., the Y-axis direction). The first portion 121 and the second portion 122 are located in two first areas 101, respectively. An upper portion 103Pof the substrate 103 is located in the second area 102, abutting the side surfaces of the first body region 131 and the second body region 132. The upper portion 103P of the substrate 103 is located between the first portion 121 and the second portion 122 of the source contact 120. The drain region 160 has the first conductivity type, such as an n-type heavily doped region, and is disposed on the back side of the substrate 103. The drain electrode 170 is disposed below the drain region 160. When the semiconductor device 100Ais turned on, current flows vertically upwards from the drain region 160, passes through the substrate 103, and towards the source region 140. Furthermore, FIG. 2 shows the relative position of the source region 140 and the source contact 120 when viewed from the YZ-plane direction. In this embodiment, as shown in FIG. 1, the source region 140 laterally abuts the source contact 120 in the X-axis direction. The source region 140 is not disposed within the source contact 120, and the bottom surface of the source region 140 is higher than the bottom surface of the source contact 120.

In addition, referring to FIG. 1 and FIG. 2, the semiconductor device 100A includes multiple body regions 130 laterally extending along the first direction (e.g., the Y-axis direction). These body regions 130 are spaced apart from each other by the upper portion 103P of the substrate 103. As shown in FIG. 2, each body region 130 has surfaces abutting the substrate 103. These surfaces include a bottom surface BS extending along the first direction (e.g., the Y-axis) and a side surface SW extending along a third direction (e.g., the Z-axis). Furthermore, each body regions 130 includes a first body region 131 with a lower doping concentration and a second body region 132 with a higher doping concentration. The second body region 132 is disposed below the first body region 131. When a bias voltage is applied to the gate electrode 114 within the trench 110, a first current channel 151 and a second current channel 152 are formed. The first current channel 151 enters each body region 130 from the bottom surface BS, passes through the second body region 132 and the first body region 131 in sequence, and reaches the source region 140. The second current channel 152 enters each body region 130 from the side surface SW, passes through only the first body region 131 but not the second body region 132, and reaches the source region 140. The first current channel 151 has a first path length L1 passing through the first body region 131, and the second current channel 152 has a second path length L2 passing through the first body region 131. The first path length L1 is less than the second path length L2.

Referring to FIG. 2, in the semiconductor device 100A, the second body region 132 and the first body region 131 in the first area 101 constitute a part of a first transistor. The first transistor has a first threshold voltage. The first current channel 151 flows vertically from the substrate 103, passes through the second body region 132 and the first body region 131 in sequence, and flows towards the source region 140. In addition, the first body region 131 in the first area 101 constitutes a part of a second transistor. The second transistor has a second threshold voltage. The second current channel 152, firstly, flows vertically upwards from the substrate 103, flows laterally from the upper portion 103P of the substrate, passes through the first body region 131, and flows towards the source region 140. The first path length L1 of the first current channel 151 passing through the first body region 131 is less than the second path length L2 of the second current channel 152 passing through the same first body region 131. Moreover, compared with the second current channel 152, the first current channel 151 further flows through the second body region 132, which has a higher doping concentration. Therefore, the first threshold voltage of the first transistor is higher than the second threshold voltage of the second transistor. The semiconductor device 100A provides two transistors with different threshold voltages connected in parallel.

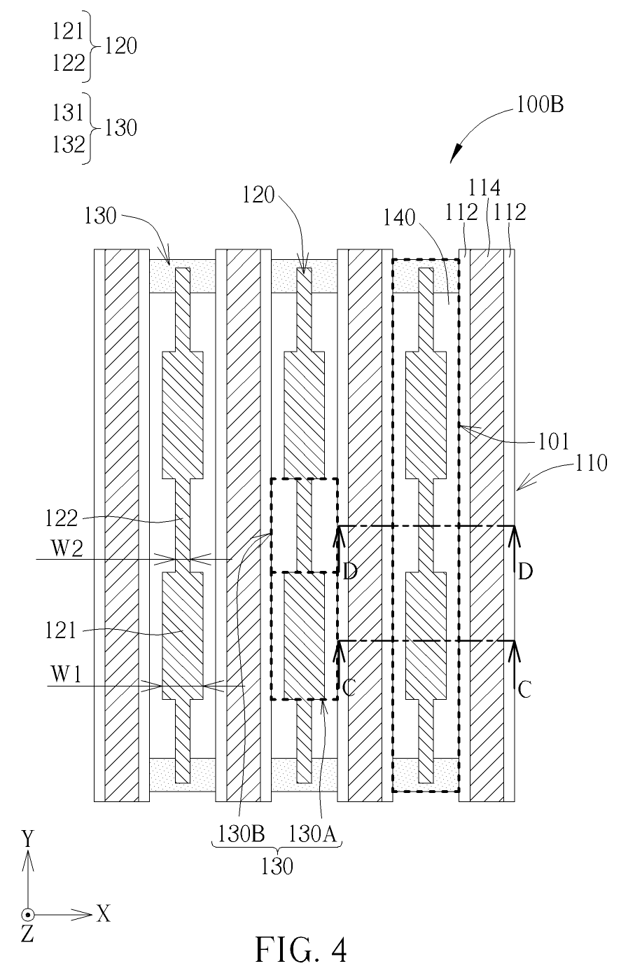

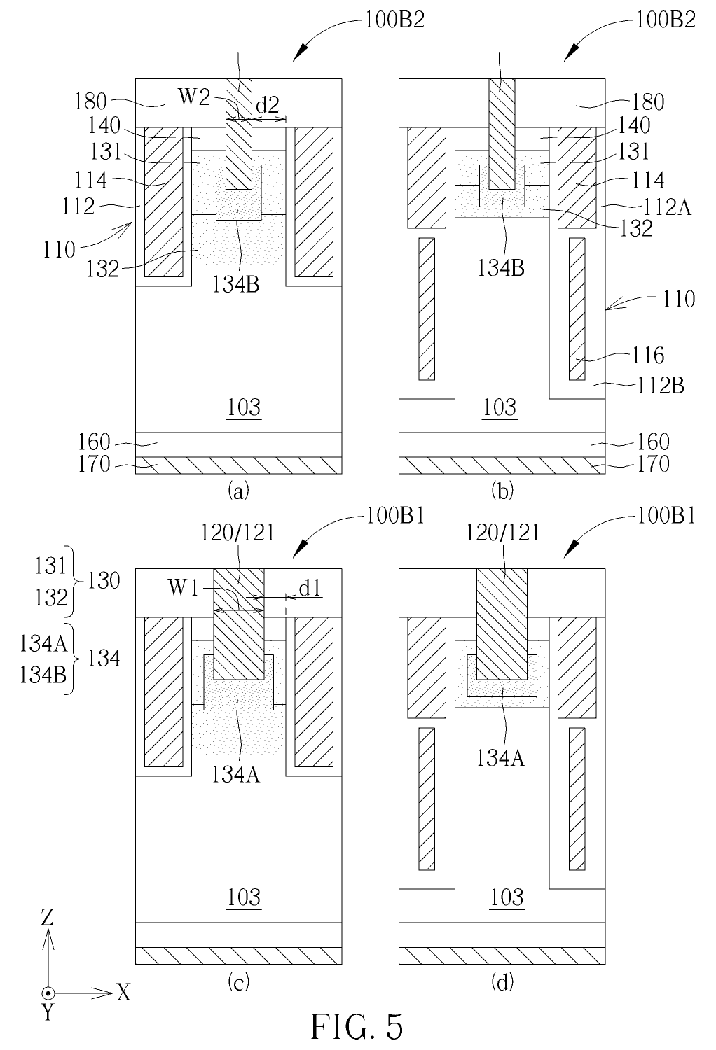

FIG. 4 is a top view of a semiconductor device 100B according to another embodiment of the present disclosure, in which the dashed frame lines indicate a first area 101, and a first segment 130A and a second segment 130B of a body region 130. FIG. 5 shows cross-sectional views (a), (b), (c), and (d) of the semiconductor device 100B according to some embodiments of the present disclosure. In FIG. 5, cross-sections (a) and (b) are taken along line D-D in FIG. 4 to show a second transistor 100B2, and cross-sections (c) and (d) are taken along line C-C in FIG. 4 to show a first transistor 100B1. The cross-sections (a) and (c) of FIG. 5 show an embodiment of the semiconductor device 100Bwithout a field plate 116, and the cross-sections (b) and (d) of FIG. 5 show another embodiment of the semiconductor device 100B including the field plate 116. Referring to FIG. 4, the source contact 120 of the semiconductor device 100B includes a first portion 121 and a second portion 122 interconnected in the first direction (e.g., the Y-axis). In a second direction (e.g., the X-axis), the first portion 121 has a first width W1, and the second portion 122 has a second width W2. The first width W1 is greater than the second width W2. In addition, referring to FIG. 5, the semiconductor device 100B further includes a heavily doped region 134 having the second conductivity type, such as a p-type heavily doped region. The heavily doped region 134 is disposed directly below the source contact 120 and in direct contact with the bottom of the source contact 120. The heavily doped region 134 includes a first heavily doped region 134A and a second heavily doped region 134B. In the embodiment of FIG. 4, during the fabrication processes of the semiconductor device 100B, the first heavily doped region 134A is formed through an etching opening for the first portion 121 of the source contact 120, and the second heavily doped region 134B is formed through an etching opening for the second portion 122 of the source contact 120. Therefore, in the second direction (e.g., the X-axis), the width of the first heavily doped region 134A is correspondingly greater than the width of the second heavily doped region 134B.

Referring to cross-sections (c) and (d) of FIG. 5, a first distance d1 is between the trench 110 and the first portion 121 of the source contact 120, and the first portion 121 of the source contact 120 provides a first transistor 100B1 with a first threshold voltage. Moreover, the first heavily doped region 134A, having the second conductivity type, such as a p-type heavily doped region, is disposed directly below and in direct contact with the bottom of the first portion 121 of the source contact 120. The doping concentration of the first heavily doped region 134A is higher than that of the second body region 132. The first heavily doped region 134A is embedded in the first body region 131 and in direct contact with the second body region 132.

Referring to the cross-sections (a) and (b) of FIG. 5, a second distance d2 is between the trench 110 and the second portion 122 of the source contact 120, where the first distance d1 is smaller than the second distance d2. The second portion 122 of the source contact 120 provides a second transistor 100B2 with a second threshold voltage. Moreover, the second heavily doped region 134B having a second conductivity type, such as a p-type heavily doped region, is disposed directly below and in direct contact with the bottom of the second portion 122 of the source contact 120. The doping concentration of the second heavily doped region 134B is the same as that of the first heavily doped region 134A. The second heavily doped region 134B is embedded in the first body region 131 and in direct contact with the second body region 132.

Furthermore, in some embodiments, as shown in cross-sections (a) and (c) of FIG. 5, a gate electrode 114 and a dielectric layer 112 are disposed in the trench 110. The dielectric layer 112 is used as a gate dielectric layer, surrounding the side and bottom surfaces of the gate electrode 114. In other embodiments, as shown in cross-sections (b) and (d) of FIG. 5, a field plate 116 is further disposed in the trench 110 and directly below the gate electrode 114. The field plate 116 is vertically spaced apart from the gate electrode 114. Moreover, a dielectric layer 112A is used as a gate dielectric layer to surround the gate electrode 114, and a dielectric layer 112B surrounds the field plate 116. The electric field is dispersed by the field plate 116, which is beneficial for improving the breakdown voltage of the semiconductor device 100B.

Referring to FIG. 4 and FIG. 5, the body region 130 of the semiconductor device 100B laterally extends along the first direction (e.g., the Y-axis) and includes a first segment 130A and a second segment 130B. The first segment 130A constitutes a part of a first transistor 100B1, which has a first threshold voltage. The cross-section of the first segment 130A, as shown in cross-sections (c) and (d) of FIG. 5, includes a first body region 131 and a second body region 132, where the doping concentration of the second body region 132 is higher than that of the first body region 131. The second segment 130B constitutes a part of a second transistor 100B2, which has a second threshold voltage. The cross-section of the second segment 130B, as shown in cross-sections (a) and (b) of FIG. 5, also includes the first body region 131 and the second body region 132. The source region 140 is disposed within the first body region 131 of both the first segment 130A and the second segment 130B. The source contact 120 extends along the first direction (e.g., the Y-axis) and includes a first portion 121 and a second portion 122. The first portion 121 is located in the first segment 130A and the second portion 122 is located in the second segment 130B. Furthermore, a first heavily doped region 134A is located in the first segment 130A, and a second heavily doped region 134B is located in the second segment 130B. The size of the first heavily doped region 134A is larger than the size of the second heavily doped region 134B.

In the semiconductor device 100B, the first width W1 of the first portion 121 of the source contact 120 is greater than the second width W2 of the second portion 122. Therefore, in the second direction (e.g., the X-axis), the first distance d1 between the first portion 121 and the trench 110 is less than the second distance d2 between the second portion 122 and the trench 110. In the fabrication processes of semiconductor device 100B, the first heavily doped region 134A is formed using the etching opening for the first portion 121 of the source contact 120, and the second heavily doped region 134B is formed using the etching opening for the second portion 122 of the source contact 120. Therefore, the width of the first heavily doped region 134A is correspondingly greater than the width of the second heavily doped region 134B. As a result, the concentration of the second conductivity type dopant in the body region 130 located in the first segment 130A is higher, and the concentration of the second conductivity type dopant in the body region 130 located in the second segment 130b is lower. This causes the first threshold voltage of the first transistor 100B1 to be higher than the second threshold voltage of the second transistor 100B2, thereby allowing the semiconductor device 100B to provide two transistors with different threshold voltages connected in parallel. The other features of the semiconductor device 100Bmay refer to the aforementioned descriptions of FIG. 2 and FIG. 3 and will not be repeated here.

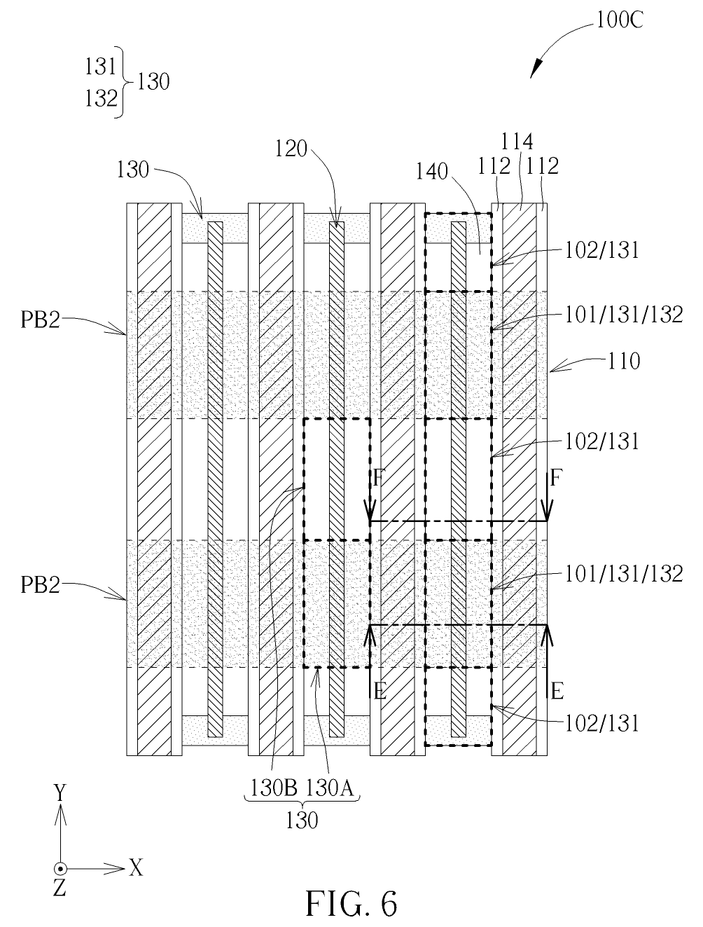

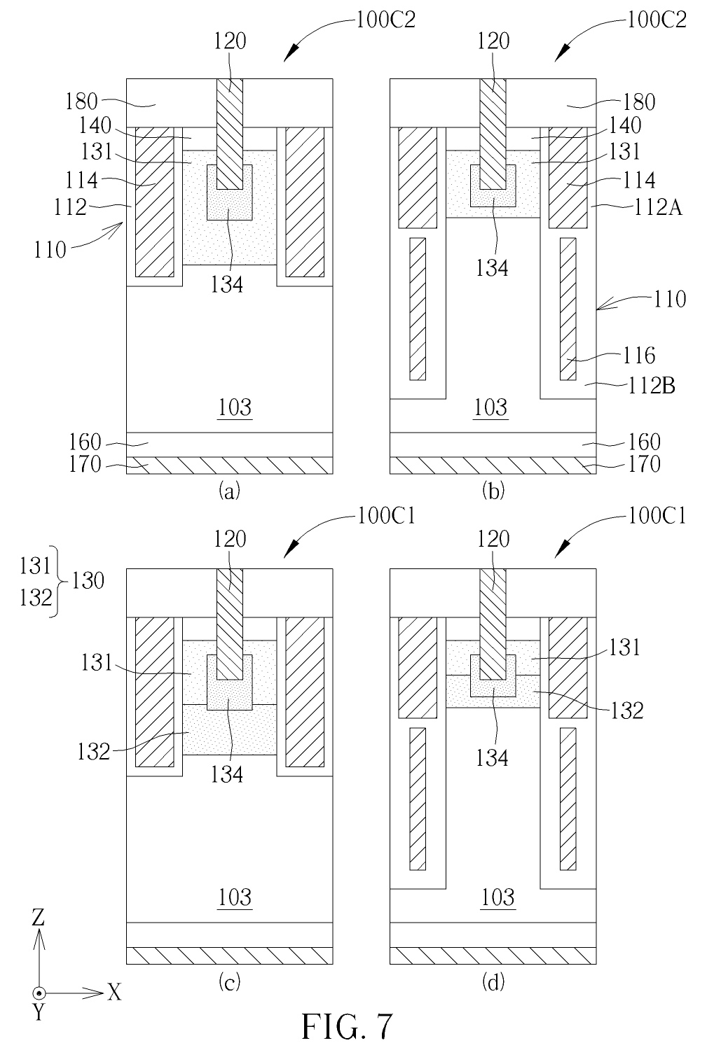

FIG. 6 is a top view of a semiconductor device 100C according to another embodiment of the present disclosure, in which the frame lines indicate a first area 101 and a second area 102, and a first segment 130A and a second segment 130B of a body region 130. FIG. 7 shows cross-sectional views (a), (b), (c), and (d) of the semiconductor device 100C according to some embodiments of the present disclosure, in which cross-sections (a) and (b) are taken along line F-F located in the second segment 130B of FIG. 6 to show a second transistor 100C2, and cross-sections (c) and (d) are taken along line E-E located in the first segment 130A of FIG. 6 to show a first transistor 100C1. The cross-sections (a) and (c) of FIG. 7 show an embodiment of the semiconductor device 100Cwithout a field plate 116, and the cross-sections (b) and (d) of FIG. 7 show another embodiment of the semiconductor device 100C including the field plate 116. Referring to FIG. 6 and FIG. 7, in semiconductor device 100C, the second area 102 abuts the first area 101, and the first body region 131 of the body region 130, the source region 140, and the source contact 120 all extend laterally from the first area 101 into the second area 102 along the first direction (e.g., the Y-axis). Moreover, the second body region 132 of the body region 130 is not disposed in the second area 102. The second body region 132 is only disposed in a region PB2. The doping concentration of the second body region 132 is higher than that of the first body region 131. Referring to FIG. 6 and FIG. 7, the first body region 131 and the second body region 132 of the body region 130 are configured differently in the first area 101 and the second area 102. Therefore, the first area 101 of the semiconductor device 100C provides a first transistor 100C1 with a first threshold voltage, and the second area 102 provides a second transistor 100C2 with a second threshold voltage, where the first threshold voltage is higher than the second threshold voltage.

Referring to FIG. 7, the semiconductor device 100C further includes a heavily doped region 134 having the second conductivity type, such as a p-type heavily doped region. The heavily doped region 134 is disposed directly below and in direct contact with the bottom of the source contact 120, and the doping concentration of the heavily doped region 134 is higher than that of the second body region 132. Furthermore, the heavily doped region 134 is embedded within the first body region 131 in both the first area 101 and the second area 102, and the heavily doped region 134 in the first area 101 is in direct contact with the second body region 132. In some embodiments, as shown in cross-sections (a) and (c) of FIG. 7, a gate electrode 114 and a dielectric layer 112 are disposed in the trench 110. In other embodiments, as shown in cross-sections (b) and (d) of FIG. 7, the gate electrode 114, a field plate 116, a dielectric layer 112A, and a dielectric layer 112B are disposed in the trench 110. The details of these features may refer to the aforementioned description of FIG. 5 and will not be repeated here.

Referring again to FIG. 6 and FIG. 7, the body region 130 laterally extends along the first direction (e.g., the Y-axis) and includes a first segment 130Aand a second segment 130B. The cross-sections (c) and (d) of FIG. 7 show the first segment 130A, which includes a first body region 131 and a second body region 132. The cross-sections (a) and (b) of FIG. 7 show the second segment 130B, which includes the first body region 131 but does not include the second body region 132. Furthermore, the source region 140 of the semiconductor device 100C is disposed within the first body region 131 and extends to both the first segment 130A and the second segment 130B. The first segment 130Aconstitutes a part of the first transistor 100C1 and causes the first transistor 100C1 to have a first threshold voltage. The second segment 130Bconstitutes a part of the second transistor 100C2 and causes the second transistor 100C2 to have a second threshold voltage. Compared with the second segment 130B, the first segment 130A further includes the second body region 132, which has a higher dopant concentration. Therefore, the first threshold voltage of the first transistor 100C1 is higher than the second threshold voltage of the second transistor 100C2.

In semiconductor device 100C, the body region 130 in the first area 101 includes the second body region 132, and the body region 130 in the second area 102 does not include the second body region 132. Using different configurations of the second body region 132 in different areas, the semiconductor device 100C provides two transistors with different threshold voltages connected in parallel. The other features of the semiconductor device 100C may refer to the aforementioned descriptions of FIG. 2 and FIG. 3 and will not be repeated here.

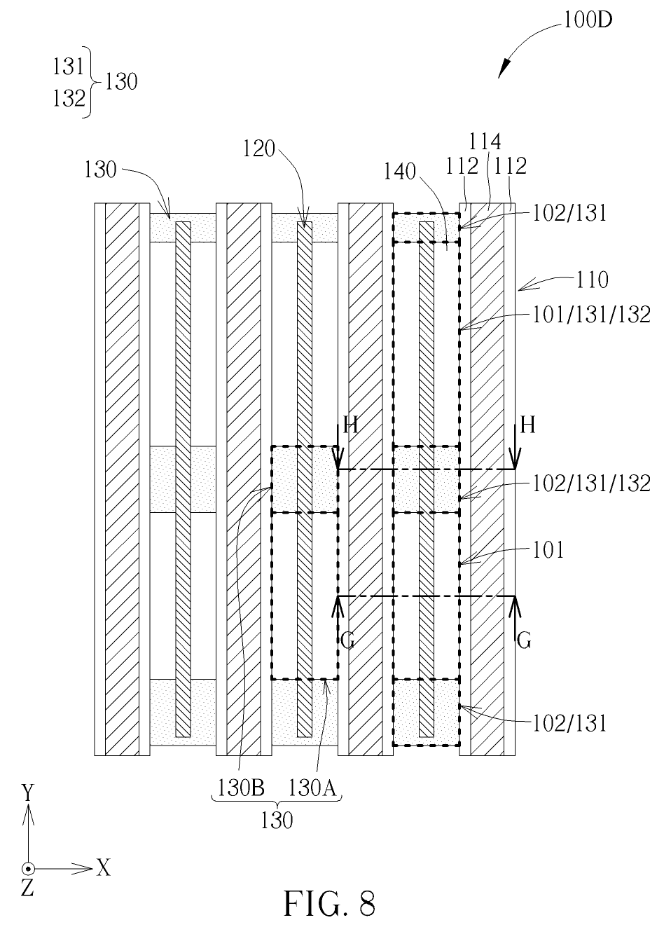

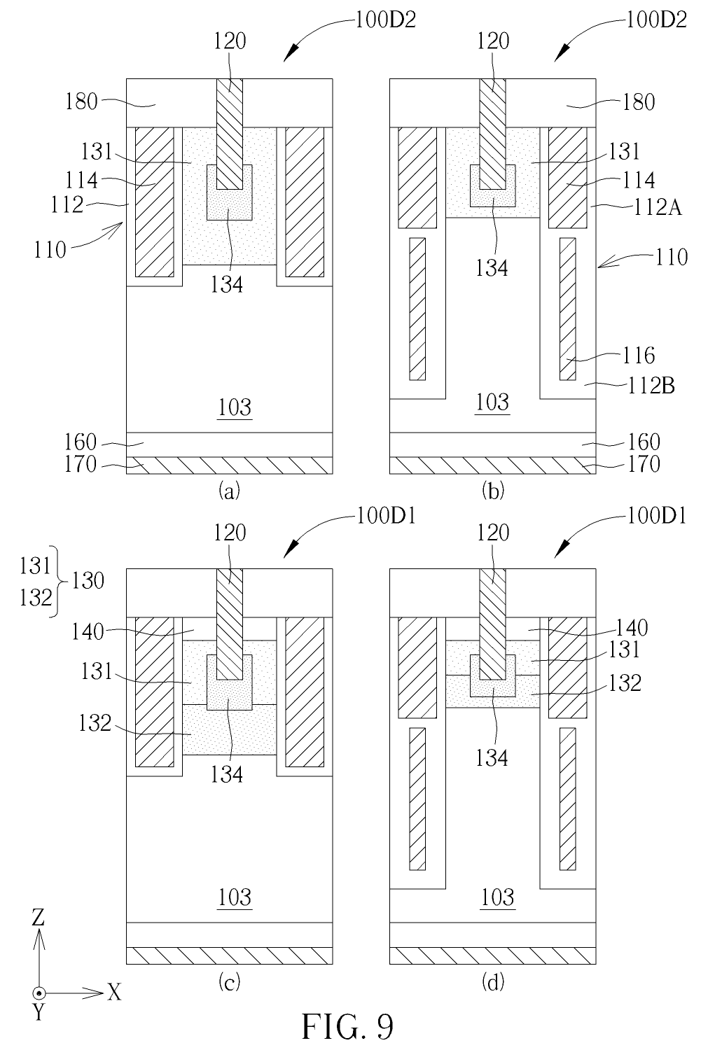

FIG. 8 is a top view of a semiconductor device 100D according to another embodiment of the present disclosure, in which the dashed frame lines indicate a first area 101 and a second area 102, and a first segment 130A and a second segment 130B of a body region 130. FIG. 9 shows cross-sectional views (a), (b), (c), and (d) of the semiconductor device 100D according to some embodiments of the present disclosure, in which cross-sections (a) and (b) are taken along line H-H in FIG. 8 to show a second transistor 100D2, and cross-sections (c) and (d) are taken along line G-G in FIG. 8 to show a first transistor 100D1. The cross-sections (a) and (c) of FIG. 9 show an embodiment of the semiconductor device 100Dwithout a field plate 116, and the cross-sections (b) and (d) of FIG. 9 show another embodiment of the semiconductor device 100D including the field plate 116. Referring to FIG. 8, in semiconductor device 100D, the second area 102 abuts the first area 101. Both the first body region 131 and the source contact 120 extend laterally from the first area 101 into the second area 102 along the first direction (e.g., the Y-axis). The second body region 132 and the source region 140 are only disposed in the first area 101, and both are not disposed in the second area 102. Referring to FIG. 8 and FIG. 9, in semiconductor device 100D, as shown in cross-sections (c) and (d) of FIG. 9, the first area 101 includes the second body region 132 and the source region 140. As shown in cross-sections (a) and (b) of FIG. 9, the second area 102 does not include the second body region 132 and the source region 140. Therefore, the first area 101 provides the first transistor 100D1 with a first threshold voltage, and the second area 102 provides the second transistor 100D2 with a second threshold voltage, where the first threshold voltage is higher than the second threshold voltage.

Referring to FIG. 9, the semiconductor device 100D further includes a heavily doped region 134 having the second conductivity type, such as a p-type heavily doped region. The heavily doped region 134 is disposed directly below and in direct contact with the bottom of the source contact 120. The doping concentration of the heavily doped region 134 is higher than that of the second body region 132. Moreover, the heavily doped region 134 is embedded in the first body region 131 of both the first area 101 and the second area 102. The heavily doped region 134 in the first area 101 is in direct contact with the second body region 132.

Referring again to FIG. 8 and FIG. 9, the body region 130 extends laterally along the first direction (e.g., the Y-axis) and includes a first segment 130A and a second segment 130B. The cross-sections (c) and (d) of FIG. 9 show the first segment 130A, which includes the source region 140, the first body region 131, and the second body region 132. The doping concentration of the second body region 132 is higher than that of the first body region 131. The cross-sections (a) and (b) of FIG. 9 show the second segment 130B, which includes the first body region 131 and does not include the second body region 132 and the source region 140. The first segment 130A constitutes a part of the first transistor 100D1 and causes the first transistor 100D1 to have a first threshold voltage. The second segment 130Bconstitutes a part of the second transistor 100D2 and causes the second transistor 100D2 to have a second threshold voltage.

In the first transistor 100D1, compared with the second segment 130B, the first segment 130A further includes the second body region 132 and the source region 140. Therefore, the current of the first transistor 100D1 flows upwards from the bottom surface of the first transistor 100D1, passes through the second body region 132 and the first body region 131 in sequence, and then flows upwards to the source region 140. In the second transistor 100D2, the second segment 130B does not have the second body region 132 and the source region 140. Therefore, the current of the second transistor 100D2, firstly, flows upwards through the first body region 131, and then flows laterally along the first direction (e.g., the Y-axis) to the source region 140 in the first segment 130A.

In the semiconductor device 100D, the source region 140 is disposed within the body region 130 in the first area 101. Moreover, the second body region 132, having a higher doping concentration, is further disposed within the body region 130 in the first area 101. The body region 130 in the second area 102 does not include the second body region 132 and does not have the source region 140 disposed therein. The body region 130 in the second area 102 only includes the first body region 131, having a lower doping concentration. Using different configurations of the second body region 132 and the source region 140 in different areas, the semiconductor device 100D provides two transistors with different threshold voltages connected in parallel. The other features of the semiconductor device 100D may refer to the aforementioned descriptions of FIG. 2, FIG. 3, and FIG. 5 and will not be repeated here.

According to some embodiments of the present disclosure, in different areas of a semiconductor device, the source contact, the source region, the body region, and/or the second body region are configured differently. Alternatively, in different areas of a semiconductor device, the width of the source contact is adjusted differently. Therefore, the semiconductor device provides different transistors with different threshold voltages connected in parallel without external circuit control. This improves the safe operating area (SOA) of the semiconductor device, satisfying the performance requirements of power components in various electronic circuit applications. Furthermore, according to the semiconductor devices of the present disclosure, different transistors with different threshold voltages are formed simultaneously in the same process steps without additional process steps and photomasks. The fabrication of the semiconductor devices of the present disclosure is compatible with current semiconductor processes, thereby saving manufacturing costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, having a first conductivity type;
a trench, extending along a first direction and disposed in the substrate;
a gate electrode, disposed in the trench;
a first body region, having a second conductivity type, disposed in the substrate and located in a first area;
a second body region, having the second conductivity type, located in the first area, disposed directly below the first body region, and in direct contact with the first body region, wherein the second body region has a doping concentration higher than a doping concentration of the first body region;
a source region, having the first conductivity type and disposed within the first body region;
a source contact, penetrating the source region and extending downwards into the first body region; and
a drain region, having the first conductivity type and disposed on a back side of the substrate.

2. The semiconductor device of claim 1, further comprising a second area, located between the first area and another first area, wherein the source contact comprises a first portion and a second portion spaced apart from each other in the first direction, and the first portion and the second portion are located in the first area and the another first area, respectively.

3. The semiconductor device of claim 2, wherein an upper portion of the substrate is located in the second area and abuts a side surface of the first body region and a side surface of the second body region, and the upper portion of the substrate is located between the first portion and the second portion of the source contact.

4. The semiconductor device of claim 3, wherein the first body region in the first area constitutes a part of a second transistor, the second transistor has a second threshold voltage, a second current channel flows laterally from the upper portion of the substrate and passes through the first body region, both the second body region and the first body region in the first area constitute a part of a first transistor, the first transistor has a first threshold voltage, a first current channel flows vertically from the substrate and passes through the second body region and the first body region in sequence, and the first threshold voltage is higher than the second threshold voltage.

5. The semiconductor device of claim 1, wherein the source contact comprises a first portion and a second portion, in a second direction, the first portion has a first width and the second portion has a second width, and the first width is greater than the second width.

6. The semiconductor device of claim 5, wherein a first distance is between the trench and the first portion of the source contact, a second distance is between the trench and the second portion of the source contact, and the first distance is less than the second distance.

7. The semiconductor device of claim 5, wherein the first portion and the second portion of the source contact are interconnected, the first portion provides a first transistor having a first threshold voltage, the second portion provides a second transistor having a second threshold voltage, and the first threshold voltage is higher than the second threshold voltage.

8. The semiconductor device of claim 5, further comprising a first heavily doped region, having the second conductivity type, disposed directly below the first portion of the source contact and in direct contact with the first portion, wherein a doping concentration of the first heavily doped region is higher than the doping concentration of the second body region.

9. The semiconductor device of claim 8, further comprising a second heavily doped region, having the second conductivity type, disposed directly below the second portion of the source contact and in direct contact with the second portion, wherein in the second direction, a width of the first heavily doped region is greater than a width of the second heavily doped region, and both the first heavily doped region and the second heavily doped region are embedded in the first body region.

10. The semiconductor device of claim 1, further comprising a second area, abutting the first area, wherein the first body region, the source region and the source contact all extend laterally from the first area into the second area, and the second body region is not disposed in the second area.

11. The semiconductor device of claim 10, wherein the first area provides a first transistor having a first threshold voltage, the second area provides a second transistor having a second threshold voltage, and the first threshold voltage is higher than the second threshold voltage.

12. The semiconductor device of claim 1, further comprising a second area, abutting the first area, wherein both the first body region and the source contact extend laterally from the first area into the second area, and both the second body region and the source region are not disposed in the second area.

13. The semiconductor device of claim 12, wherein the first area provides a first transistor having a first threshold voltage, the second area provides a second transistor having a second threshold voltage, and the first threshold voltage is higher than the second threshold voltage.

14. The semiconductor device of claim 1, further comprising a heavily doped region, having the second conductivity type, disposed directly below the source contact and in direct contact with a bottom of the source contact, wherein a doping concentration of the heavily doped region is higher than the doping concentration of the second body region.

15. The semiconductor device of claim 14, wherein the heavily doped region is embedded in the first body region, and the heavily doped region in the first area is in direct contact with the second body region.

16. A semiconductor device, comprising:
a substrate, having a first conductivity type;
a trench, extending along a first direction and disposed in the substrate;
a gate electrode, disposed in the trench;
a source region, having the first conductivity type and adjacent to the gate electrode; and
a body region, extending along the first direction, and comprising a first segment and a second segment, wherein the first segment comprises a first body region and a second body region, the second segment comprises the first body region, and a doping concentration of the second body region is higher than a doping concentration of the first body region;
wherein the first segment constitutes a part of a first transistor, the first transistor has a first threshold voltage, the second segment constitutes a part of a second transistor, the second transistor has a second threshold voltage, and the first threshold voltage is higher than the second threshold voltage.

17. The semiconductor device of claim 16, wherein the second segment does not comprises the second body region, and the source region is disposed within the first body region of both the first segment and the second segment.

18. The semiconductor device of claim 16, wherein the second segment does not comprises the second body region, and the source region is disposed in the first segment and not in the second segment.

19. The semiconductor device of claim 16, wherein the second segment further comprises the second body region, and the source region is disposed in the first body region of both the first segment and the second segment, the semiconductor device further comprises:
a source contact, extending along the first direction, and comprising a first portion and a second portion, wherein in a second direction, a width of the first portion is greater than a width of the second portion, the first portion is located in the first segment, and the second portion is located in the second segment.

20. The semiconductor device of claim 19, further comprising:
a heavily doped region, having a second conductivity type, disposed directly below the source contact and in direct contact with a bottom of the source contact, wherein the heavily doped region comprises a first heavily doped region and a second heavily doped region, located in the first segment and the second segment, respectively, and a size of the first heavily doped region is larger than a size of the second heavily doped region.

21. A semiconductor device, comprising:
a substrate, having a first conductivity type;
a trench, extending along a first direction and disposed in the substrate;
a gate electrode, disposed in the trench;
a source region, having the first conductivity type and adjacent to the gate electrode; and
a plurality of body regions, extending along the first direction, wherein the plurality of body regions is spaced apart from each other by the substrate, each of the plurality of body regions has surfaces abutting the substrate, and the surfaces comprise a bottom surface extending along the first direction and a side surface extending along a second direction,
wherein each of the plurality of body regions comprises a first body region with a lower doping concentration and a second body region with a higher doping concentration, and the second body region is disposed below the first body region; and
when a bias voltage is applied to the gate electrode, a first current channel and a second current channel are formed, the first current channel enters each of the plurality of body regions from the bottom surface, passes through the second body region and the first body region to reach the source region; and the second current channel enters each of the plurality of body regions from the side surface, passes through the first body region, not through the second body region to reach the source region.

22. The semiconductor device of claim 21, wherein the first current channel has a first path length passing through the first body region, the second current channel has a second path length passing through the first body region, and the first path length is less than the second path length.
